(19) United States
(12) Patent Application Publication
(10) Pub. No.: US 2004/0170073 A1
(43) Pub. Date: Sep. 2, 2004

(54) Semiconductor storage unit

(76) Inventor: Tetsuya Kaneko, Chiba-shi (JP)

Correspondence Address: ADAMS & WILKS, 31st Floor, 50 Broadway, New York, NY, 10004, US

(21) Appl. No.: 10/744,819

(22) Filed: Dec. 23, 2003

(30) Foreign Application Priority Data
Dec. 26, 2002 (JP) 2002-376095

(51) Int. Cl. G11C 7/00; G11C 29/00

(52) U.S. Cl. 365/200

(57) ABSTRACT

Provided is a semiconductor storage unit in which semiconductor storage unit manufacturers can protect data in their products after the products are put on the market. The semiconductor storage unit includes: a user memory that serves to one of reading and writing of data and is accessible upon a first instruction; a redundant memory that serves to one of reading and writing of data and is accessible upon a second instruction; an input control circuit for outputting a signal after analyzing the instructions that are inputted to the input interface; an access control circuit for allowing access to the user memory or the redundant memory; an address decoder that outputs, a signal for choosing a memory cell of the user memory or of the redundant memory to the user memory or to the redundant memory; and an output control circuit for reading data of the user memory or the redundant memory.

### BACKGROUND OF THE INVENTION

1. Field of the Invention

The present invention relates to a semiconductor storage unit that is electrically rewritable.

2. Description of the Related Art

Conventional redundant memories are built in as condition memories to prohibit writing (see JP 01-188967 A (Pages 2 to 3, Fig. 1), for example).

The condition memories are redundant memories for storing what is written in a user memory in order to avoid erroneous writing caused by malfunction, noise, or the like. Data in the condition memories are rewritable by a user, and therefore unfit to be used for any statistical or research purpose by semiconductor storage unit manufacturers.

Up to now, protection is not ensured for such data as the serial number and the date of manufacture, namely, data that are written for product traceabilityby semiconductor storage unit manufacturers, since every memory region is accessible and rewritable by a user requiring no special procedure and any user could change those product tracking information.

### SUMMARY OF THE INVENTION

The present invention has been made to solve the above problem, and an object of the present invention is therefore to protect, without fail, data written in memories by semiconductor storage unit manufacturers from users without requiring building of some system on users' part. To attain this object, the present inventors have taken the following measures.

A semiconductor storage unit according to the present invention includes a redundant memory region in addition to a user memory region in which a user has access to any arbitrary address.

The user memory region is a memory array in which arbitrary data are stored to be read or written upon input of a given access instruction through the input interface arranged in the IC.

The redundant memory region is a memory array in which arbitrary data are stored to be read or written upon input of a given access instruction, which is different from the access instruction of the user memory region, through an input interface arranged in an IC.

Moreover, according to the present invention, access by a user to the redundant memory region is restricted to thereby protect data in the redundant memory from a reading/writing operation carried out by a user.

Moreover, according to the present invention, the redundant memory is composed of a non-volatile memory and therefore data in the redundant memory can be protected regardless of whether a power supply voltage is turned on or off. This provides an improved level of data protection.

According to another aspect of the present invention, the redundant memory is composed of a volatile memory and therefore information stored in the redundant memory is initialized as the power is turned off. This saves labor of initializing the redundant memory, thereby improving the convenience of use.

Moreover, according to the present invention, the redundant memory can be utilized as a user memory by giving a predetermined instruction through an input interface. This provides a protecting function as well as a user memory in which a user can write arbitrary data, thereby improving the convenience of use.

### BRIEF DESCRIPTION OF THE DRAWING

In the accompanying drawings,

FIG. 1 is a diagram showing a circuit structure of a memory circuit according to Embodiment 1 of the present invention.

### DETAILED DESCRIPTION OF THE PREFERRED EMBODIMENT

A semiconductor storage unit according to the present invention includes a user memory that serves to one of reading and writing of data and is accessible upon a first instruction and a redundant memory that serves to one of reading and writing of data and is accessible upon a second instruction. Further, the semiconductor storage unit includes an input interface to which the first and second instructions are inputted, an input control circuit for outputting a signal after analyzing the instructions that are inputted to the input interface, and an access control circuit for allowing access to one of the user memory and the redundant memory in response to the signal of the input control circuit. Further, the semiconductor storage unit includes an address decoder that outputs, in response to the signal of the input control circuit and the signal of the access control circuit, a signal for choosing one of a memory cell of the user memory and a memory cell of the redundant memory to one of the user memory and the redundant memory, an output control circuit for reading one of the data of the user memory and the data of the redundant memory in response to the signal of the access control circuit, and an output interface to which an output signal of the output control circuit is inputted.

Hereinafter, a detailed description is given with reference to the accompanying drawing on a specific example of an embodiment according to the present invention.

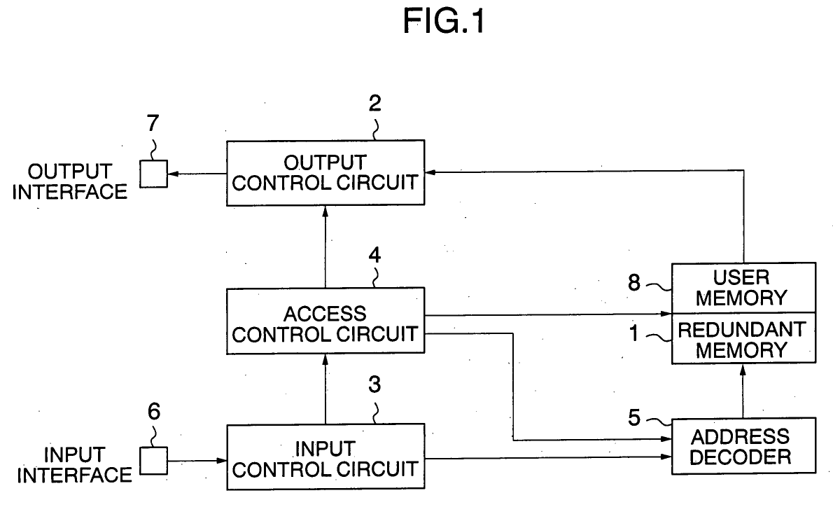

The structure of a memory circuit of the present invention will be described in detail. FIG. 1 is a block diagram showing a structure of a memory circuit according to Embodiment 1 of the present invention. The memory circuit is composed of a user memory region 8 in which a user can write arbitrary data, a redundant memory region 1 in which a semiconductor storage unit manufacturer stores data, an output control circuit 2 for reading data of the user memory or the redundant memory, an input control circuit 3 for analyzing an instruction that commands access to the user memory or the redundant memory, an access control circuit 4 for allowing access to the user memory or the redundant memory, and an address decoder 5 for choosing a memory cell.

The user memory region 8 is a memory array in which arbitrary data can be stored to be read or written upon input of a given instruction through an input interface 6 that is arranged in an IC.

The redundant memory 1 is a memory array in which a manufacturer can read or write arbitrary data upon input of a given instruction which is different from access of the user memory through the input interface 6 that is arranged in the IC.

In writing arbitrary data in an EEPROM, a user or a semiconductor storage unit manufacturer inputs a signal, address, or data corresponding to a given instruction through an input interface of the IC. Usually, when the input control circuit 3 and the access control circuit 4 of an.EEPROM receive a writing instruction, the address decoder 5 chooses the address in question and accesses the address.

According to the present invention, the access control circuit decides, upon receiving an instruction, whether or not to execute the instruction of reading/writing data of the user memory or the redundant memory.

To give an example, in the case where a user inputs a usual command, the user memory region is chosen while the redundant memory region is left unchosen. As a result, reading/writing of data of the user memory region is carried out while no data is read from or written in the redundant memory region. If a semiconductor storage unit manufacturer desires access to the redundant memory region for product traceability, a given instruction, which is different from the usual command, has to be inputted to enable the manufacturer to read or write data of the redundant memory. This makes it impossible for a user who does not have a knowledge of a given instruction recognition process to access the redundant memory.

The semiconductor storage unit manufacturer thus can protect the data (a date of manufacture, a serial number, and the like) from a user, managing the product in the market through ensuring product traceability.

Similar to the user memory, the redundant memory is characterized in that, in the case of an electrically writable/erasable semiconductor storage device, additional peripheral circuits are not necessary because EEPROM circuits can be used for a reading circuit for reading data of the redundant memory and for a writing circuit for writing data.

Employed for the redundant memory is a non-volatile memory such as a mask ROM. EPROM, EEPROM, Flash-EEPROM, fuse, gate array, or MRAM, or a volatile memory such as an SRAM or DRAM.

Since reading/writing of data of the redundant memory is allowed by inputting a given instruction, a user can obtain product tracking information and management of the product in the market can readily be achieved by a user.

As described above, according to the present invention, semiconductor storage unit manufactures can protect data in their products after the products are put on the market without needing special peripheral circuits or software, and users' burden is. lightened.

What is claimed is:

1. A semiconductor storage unit comprising:
a user memory that serves to one of reading and writing of data and is accessible upon a first instruction;
a redundant memory that serves to one of reading and writing of data and is accessible upon a second instruction;
an input interface to which the first and second instructions are inputted;
an input control circuit for outputting a signal after analyzing the instructions that are inputted to the input interface;
an access control circuit for allowing access to one of the user memory and the redundant memory in response to the signal of the input control circuit;
an address decoder that outputs, in response to the signal of the input control circuit and the signal of the access control circuit, a signal for choosing one of a memory cell of the user memory and a memory cell of the redundant memory to one of the user memory and the redundant memory;
an output control circuit for reading one of the data of the user memory and the data of the redundant memory in response to the signal of the access control circuit; and
an output interface to which an output signal of the output control circuit is inputted.

2. A semiconductor storage unit in which data is electrically written and from which data is electrically erased, comprising:
a user memory region accessible by a user; and
a redundant memory region separate from the user memory region
wherein data other than ones that a user stores can be stored.

3. A semiconductor storage unit according to claim 2, wherein:
a user is prohibited from writing arbitrary data in the redundant memory; and
data can be written in the redundant memory only when a predetermined instruction is given through an input interface.

4. A semiconductor storage unit according to claim 2, wherein the redundant memory is non-volatile and information stored is kept regardless of whether a power supply voltage is turned on or off.

5. A semiconductor storage unit according to claim 2, wherein the redundant memory is volatile, initializes stored information when the power is turned off, and keeps data stored in the redundant memory since the last time the power is turned on.

6. A semiconductor storage unit according to claim 2, wherein a user is allowed to write arbitrary data in the redundant memory, enabling the redundant memory to be used as a user memory.
